(19) United States
(12) Patent Application Publication
(10) Pub. No.: US 2004/0012301 A1
(43) Pub. Date: Jan. 22, 2004

(54) Actuating member and method for producing the same

(76) Inventors: Mohamed Yahia Benslimane, Nordborg (DK); Peter Gravesen, Nordborg (DK)

Correspondence Address: McCormick Paulding & Huber, City Place II, 185 Asylum Street, Hartford, CT, 06103-4102, US

(21) Appl. No.: 10/415,631

(22) PCT Filed: Oct. 31, 2001
(86) PCT No.: PCT/DK01/00719

(30) Foreign Application Priority Data
Nov. 2, 2000 (DE) 100 54 247.6

(51) Int. Cl. H01L 41/18

(52) U.S. Cl. 310/311; 310/328

(57) ABSTRACT

The invention relates to anactuating member comprising an elastomer body that is provided with one electrode each on opposite peripheries. The aim of the invention is to improve the dynamism of such an actuating member. To this end, at least one periphery is provided with at least one waved section that comprises elevations and depressions as the extremes disposed in parallel to the cross direction. Said section is covered by an electrode that completely covers at least a part of the extremes and that extends across the waved section.

### CROSS-REFERENCE TO RELATED APPLICATIONS

This application is entitled to the benefit of and incorporates by reference essential subject matter disclosed in International Application No. PCT/DK01/00719 filed on Oct. 31, 2001 and German Patent Application No. 100 54 247.6 filed on Nov. 2, 2000.

### FIELD OF THE INVENTION

The invention concerns an actuating member with a body of elastomer material which body on each of two boundary surfaces lying oppositely to one another is provided with an electrode. The invention further concerns a method for making an actuating member with a body of elastomer material which on two oppositely lying sides is provided with electrodes.

### BACKGROUND OF THE INVENTION

One such actuating member is known from U.S. Pat. No. 5,977,685. Such actuating members have also been used in connection with “artificial muscles” because their behavior under certain conditions corresponds to that of human muscles.

The functionality is relatively simple. If a voltage difference is applied to the two electrodes an electric field is created through the body which electric field exerts a mechanical attraction force between the electrodes. This leads to a drawing near of the two electrode arrangements and to an associated compression of the body. The drawing near of the electrodes can be further supported if the material of the body has dielectric properties. Since the material, however, has an essentially constant volume, the compression therefore leads to a decrease in thickness and to an increase in the measurements of the body in the other two directions, that is parallel to the electrodes.

If one now limits the extensibility of the body in one direction, then the thickness change is converted entirely into a change of length in the other direction. For the following explanation, the direction in which the change of length is to take place is referred to as the “longitudinal direction”. The direction, in which a change in length is not to take place, is referred to as the “transverse direction”. In the known case the electrode has a conducting layer with a relatively low conductivity on which layer strips of non-flexible material running in the transverse direction are carried with the strips in the longitudinal direction being spaced from one another. The conductive layer is to provide a most uniform distribution of the electric field, while the strips, preferably of metal, are to inhibit the widening of the body in the transverse direction. Above all, this, because of the poor conductivity of the electric conducting layer, results in a certain limiting of the dynamism of the actuating member.

The invention has as its object the improvement of the mechanical extensibility of an actuating element.

### SUMMARY OF THE INVENTION

This object is solved by an actuating member of the previously mentioned kind which has at least one boundary surface with a waved region with heights and depths as extremes running parallel to one another in the transverse direction, which body is covered by an electrode that completely covers at least a part of the extremes and which extends continuously over the waved region.

With this development, one achieves several advantages: since the electrode is formed throughout in the transverse direction, it limits the extension of the body in this transverse direction. “Throughout” here means that the electrode has such a shape that it can not be further stretched, for example, a straight line shape. The entire deformation, which results from a decrease in the thickness of the body, is converted to a change in extension in the longitudinal direction. Naturally in practice because of real materials a change in the transverse direction is also obtained. This is however, in comparison to the change of the extension in the longitudinal direction, negligible. Since the electrode extends continuously over the entire waved region, it is assured that the electric conductivity of the electrode is large enough so that the formation of the electric field, which is required for the reduction of the thickness of the body, occurs rapidly. One can therefore positively realize a high frequency with the actuating member. Since the outer surface of the body is provided with at least one waved region and the waves run parallel to the transverse direction, in the longitudinal direction an outer surface stands available which at least in the rest condition of the actuating member is essentially larger than the longitudinal extent of the actuating member. If one therefore enlarges the longitudinal extent of the actuating member, then only the waves are flattened, that is the difference between the extremes, in other words the crests of the heights and the valleys of the depths, becomes smaller. An electrode, which is applied to this surface, can accordingly follow the stretching without problem without the danger existing that the electrode becomes loosened from the surface. By way of the waved surface one achieves therefore an outstanding stiffness in the transverse direction, a good flexibility in the longitudinal direction, and simple to realize possibility that the electrical voltage supply for creating the electric field can be distributed uniformly over the entire surface of the body. The expression “waved” does not mean that only bow shaped or sinusoidally shaped contours are of concern. Basically, it is taken here that any structure is imaginable and permissible in which “crests” and “valleys” alternate with the crests and valleys extending in the transverse direction, that is in a direction which runs at a right angle to the extension direction. In cross section, it can therefore concern a sine wave, a triangular wave, a saw tooth wave, a trapezoidal wave or a rectangular wave. The extensibility is improved without influencing the dynamism of the actuating member.

Preferably, the electrode completely covers the surface of the waved region. A sheet-like electrode is therefore used so that the electrical charge can be transferred to every point of the boundary surface of the body so that the build up of the electric field occurs uniformly. At the same time, it allows the stiffness in the transverse direction to be further improved because not only the extremes, that is the tops of the crests and the bottoms of the valleys, are covered with the through going electrode, but also covered are the flanks between the crests and the valleys. Yet, the movablility in the longitudinal direction essentially changes not at all. When the body extends in the longitudinal direction, the contours flatten, without anything having to change in the arrangement between the electrode and the body.

It is especially preferred that the electrode be directly connected with the body. An additional conductive layer is more over not necessary, because the electrode takes over the electrical conduction for the entire boundary surface. If the electrode is directly connected with the body, the influence of the electrode on the body is better, which manifests itself especially in an improved stiffness or non-extensibility in the transverse direction.

Preferably, the extremes have amplitudes, which are not larger than 20% of the thickness of the body between the boundary surfaces. With these dimensions, one achieves a uniform distribution of the electric field over the length of the actuating member, that is the forces work uniformly on the body, without them being concentrated in especially pronounced strips. The word “amplitude” is here understood to mean half of the difference between neighboring extremes, that is half of the spacing between a height and a depth.

Preferably, the electrode has a thickness which maximally amounts to 10% of the amplitude. The extensibility factor (compliance factor) Q of an actuating member is directly proportional to the ratio between the amplitude and the thickness of the electrode. The larger this ratio becomes, the larger becomes the extensibility factor.

Preferably, the ratio between the amplitude and the period length lies in the range of 0.08 to 0.25. This ratio between amplitude and period length has an effect on the length of the outer surface of a period. The larger the length of the outer surface, the larger is basically the extensibility. Theoretically, the body 10 extend until the outer surface is smooth, without having the electrode move over the underlying outer surface. In practice, the extensibility is however limited by other parameters.

Preferably, the waved region has a rectangular profile. It has been observed that this best allows extension in the longitudinal direction. One leads back from this that the electrode lends to the outer surface a certain stiffness in the longitudinal direction. For example, one can imagine in the case of a rectangle that the portions which lie parallel to the longitudinal extent of the rectangular profile at the heights and depths can not themselves become extended. The extension of the body therefore occurs practically exclusively in the increasing of the inclination of the flanks and in the therewith associated decreasing of the amplitude.

Preferably, the rectangular profile has teeth and teeth gaps which in the longitudinal direction are of the same length. This makes it possible that the electric field is formed with most pausible uniformity. At the same time, this shape simplifies the manufacturing.

The object is solved by a method of the previously mentioned type in that an elastomer is pressed into a mold with a waved surface profile to form a film, which film is then hardened for such short time that it remains still formable, then a further mold with a waved surface is pressed against the other side of the film, and after the formation of the outer surface shapes, a conducting layer is applied to the outer surfaces.

Such type of manufacturing is relatively simple. A processing of the electrode can basically be omitted. It is only necessary that the desired outer surface structure be created. One such outer surface structure is created by the mold pressing. With this, it is only necessary that molds with corresponding structures be available for use. Such molds can be achieved through the use of known photolithographic processes, such as known for example, from the manufacturing of compact disks (CD's).

It is especially preferred that the conducting layer be applied evaporatively. An evaporatively applied layer allows the desired small thickness to be realized. One can moreover make certain that the evaporated material can also penetrate into narrow valleys and there form an electrode.

### BRIEF DESCRIPTION OF THE DRAWINGS

The invention is described in more detail in the following by way of a preferred exemplary embodiment in combination with the drawings. The drawings are:

FIG. 1 a schematic view with different method steps for the making of an actuating member,

FIG. 2 a cross sectional view through one period,

FIG. 3 a curve for elucidating relationships in the case of a sinusoidal profile, and

FIG. 4 the same curve for elucidating relationships in the case of a rectangular profile.

### DETAILED DESCRIPTION OF THE PREFERRED EMBODIMENTS

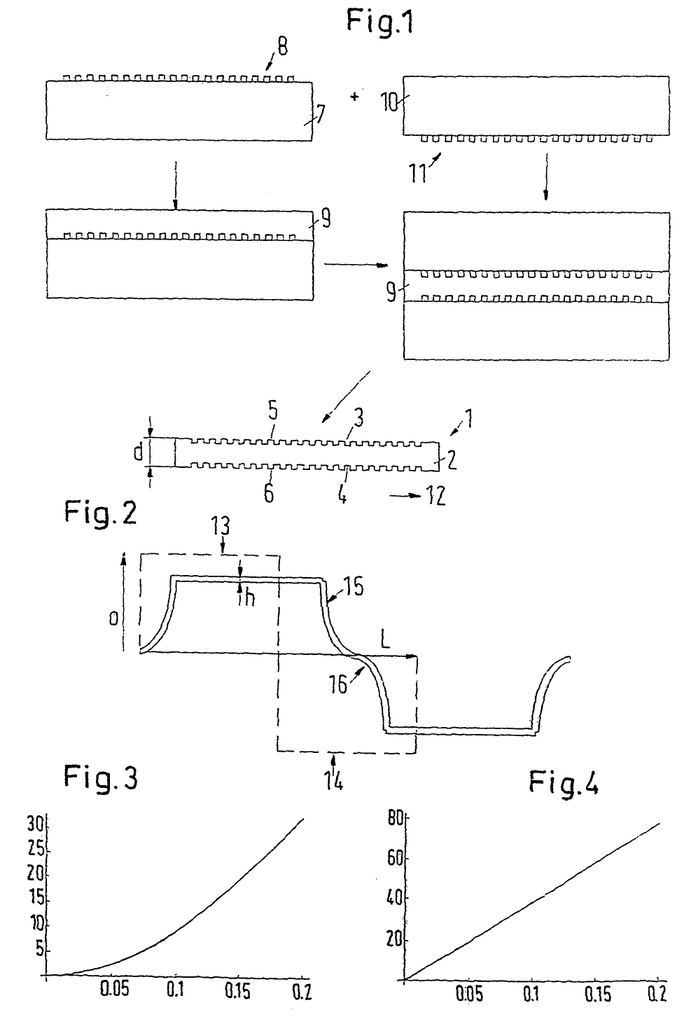

FIG. 1 shows different steps for the making of an actuating member 1 with a body 2, which body has two boundary surfaces 3, 4 lying oppositely to one another. Applied to each of the boundary surfaces 3, 4 is an electrode 5, 6, respectively. The electrodes 5, 6 are directly connected to the body 2. The body 2 is formed of an elastomer material, for example, a silicone elastomer, and preferably has dielectric properties. The material of the body 2 is of course deformable. It has however, a constant volume, that is if one compresses the body 2 in the direction of the thickness d there then results an increase in the extent of the body 2 in the two other directions. If one then limits the extension of the body 2 in one direction, the decrease in the thickness d leads entirely to an increase of the extension of the body 2 in the other direction. In the case of the exemplary embodiment of FIG. 1 the extension possibility perpendicular to the plane of the drawing (transverse direction) is to be limited or even can be entirely eliminated. In the direction from the left to right (with reference to FIG. 1), that is the longitudinal direction, there is on the other hand to be an extension possibility. This anisotropic relationship is achieved in that the two boundary surfaces 3, 4 of the body 2 have a waved structure. In FIG. 1 this waved structure is illustrated as being a rectangular profile. It is however also possible that the waved structure can be formed as a sinusoidal profile, a triangular profile, a saw tooth profile, or a trapezoidal profile.

It lies without anything further on the fact that an inextensible electrode 5, 6 is directly rigidly fixed to the body 2, which electrode inhibits an extension of the body 2 perpendicularly to the drawing plane, when the body 2 is compressed in the direction of its thickness (d). An extension perpendicularly to the drawing plane would require that the electrodes of 5, 6, also be extensible in this direction which definitionally is not the case. The compressing of the body occurs in that the electrodes of 5, 6 have applied to them a voltage difference, so that an electric field is formed between the two electrodes of 5, 6, which in turn exerts forces which lead to the two electrodes 5, 6 being drawn toward one another. A requirement here is that the body 2 not be too thick. Preferably, the thickness d of the body 2 is in the range of from a few to approximately 10 μm.

The table below shows typical values for electrode layers and elastomers as well as typical values of the activating voltage for an actuating member.

| | | Elastomer | | | | | |
|---|---|---|---|---|---|---|---|
| Elastomer | | | | Electrode | | | |
| Dielectric | Elastomer | Modulus of | Electrode | Modulus of | Electrode | Electrode | Activating |
| Constant | Thickness | Elasticity | Thickness | Elasticity | Area | Resistance | Voltage |
| [−] | [μm] | [MPa] | [A] | [GPa] | [cm^{2]} | [KOhm] | [V] |
| 2-6 | 10-100 | 0.3-10 | 100-5000 | 1-80 | 1-10000 | 0.05-1000 | 100-5000 |

In the following we consider a 20 μm thick silicone elastomer film with a modulus of elasticity of 0.7 MPa and a dielectric constant of 3. The electrodes are made of gold and have a thickness of 0.05 μm as well as a modulus of elasticity of 80000 MPa. The capacitance of such an actuating member amounts to 0.1 nF/cm², and the step response lies in the size order of microseconds for the non-loaded actuating member. If one assumes an extensibility factor of 4000 for the electrodes, 1000 V are necessary to create an enlargement of the size order by 10%, where as an increase of less than 0.05% is created in the case of an unstretchable electrode, that is an electrode with an extensibility factor of 1. In other words, the invention makes it possible to lower the activating voltage.

The making of a body such as the body 2 is relatively simple. A mold 7 with a corresponding negatively waved structure, here a rectangular structure, is coated with an elastomer solution, in order to form a thin film having in a typical case a thickness of 20 to 30 μm. The film 9 is then hardened for a short time so that it forms a relatively soft layer which can still be later shaped. Then a second mold 10 with a corresponding surface structure 11 is pressed onto the other side of the elastomer film 9, with both pressing processes being carried out under vacuum to prevent the inclusion of air at the contacting surfaces between the molds and film. The entire sandwich arrangement of film 9 and molds 7, 10 is then completely hardened. When the molds 7, 10 are mechanically removed, the film 9 has the illustrated waved boundary surfaces 3, 4. Subsequently, practically any conductive layer can be applied to the waved boundary surfaces 3, 4. For example, a metal layer of gold, silver, or copper can be applied by evaporation.

The effect of the waved surface structure is shown by the schematic illustration of FIG. 2. A rectangular profile in its rest position, that is without the application of an electric voltage to the electrode 5, 6, is illustrated by the dashed lines. The rectangular profile has an amplitude a and a cycle or period length L. The thickness of the conductive layer 5 is h. In this case, the amplitude is taken to be half of the difference between a height 13 and a depth 14, which values can also be designated by the words “crest” and “valley”. All together both terms are taken to signify “extreme”. As is to be seen from FIGS. 1 and 2, the height 13 and the depth 14 in the longitudinal direction 12 have the same extent. The longitudinal direction 12 runs in FIG. 2 from left to right. The solid lines illustrate the form of the rectangular profile when the body is enlarged in the longitudinal direction. Since the material of the body 2 has a constant volume, an extension in the longitudinal direction 12 means at the same time that the profile flattens in the thickness direction, with the thickness decrease being greatly exaggerated in the illustration for explanation purposes. This profile is now illustrated with solid lines.

It is to be seen that the profile in the region of the height 13 and the depth 14 is practically not enlarged. A lengthening of the body 10 is thereby possible only at the flanks 15, 16 and indeed without the electrodes which are fastened to them in some way having to stretch.

One can now establish different relations which have especially advantageous characteristics.

Thus, the relationship between the amplitude a of the profile and the thickness h of the conductive coating, which forms the electrodes (5, 6) determines the extensibility of the waved electrode and therewith the extensibility of the body (2). For waved profiles, an extensibility factor Q is directly proportional to the square of this relationship. By an optimization of this relationship, it is theoretically possible to increase the extensibility by a factor of 10000 and above. If one for example has a coating thickness of 0.02 μm and an amplitude of 2 μm, the relationship is 100 and the extensibility factor is 10,000.

For a rectangular profile, such as illustrated in FIG. 2, the extensibility factor Q can easily be calculated from the bending beam theory.

$$Q = 16 \frac{a}{L} {( \frac{a}{h} )}^{2} = 16 {v ( \frac{a}{h} )}^{2} , where v = \frac{a}{L} .$$

For sinusoidal or triangular shaped profiles, the same basically holds, with the constant factor (16 for the rectangular profile) being smaller for the sinusoidal or triangular profile. Further, one must take into account the relationship between the entire length s of one period of the profile and the length of the period itself. The length s is obtained if the profile “draws straight”. In the case of the rectangular profile, the resulting length s equals L+4a. If the relationship s/L is close to 1, then the actuating member will be not very strongly moved even if the electrode is very flexible.

In FIGS. 3 and 4 is shown the relationship between, to the right, the ratio of the amplitude a to the period length L and, toward upwardly, the quantity of 100%×(s−L)/L, with FIG. 3 being for a sinusoidal profile and FIG. 4 being for a rectangular profile. In practice, one requires a maximal lengthening of 20% to 50%, so that it moves an “artificial muscle” by about 10% to 25%. That means that the relationship V=a/L should move in the range of from 0.1 to 0.2 if a rectangular profile is used.

Theoretically one can achieve with a sinusoidal profile a lengthening of about 32% and with a rectangular profile a lengthening of nearly 80%. In practice, however, this is not the case, because for example, the rectangular profile consists of vertical and horizontal sections with only the first named sections contributing to the flexibility of stretchability. The horizontal sections of the electrodes are themselves, not stretched.

In a practical exemplary embodiment, one makes a mold 7 with the help of photolithography, with one illuminating and developing a positive photoresist. In this case, the mask used for the illumination is relatively simple. It consists of parallel rectangles with a width of 5 μm and a length which is determined by the size of the substrate. The rectangles are uniformly spaced by 5 μm and are multiplely repeated in the stretching direction. The height of the profile, that is the amplitude, is defined as the half of the thickness of the photoresist layer which is laid down onto the substrate. This height can also be chosen to be about 5 μm.

For a uniform electric field, it is advantageous if the amplitude is at least 10 times smaller than the thickness d of the body 2. For an elastomer film with a thickness of 20 μm one chooses advantageously a maximum amplitude height of 2 μm.

1. An actuating member with a body of elastomer material, which body on each of two boundary surfaces lying oppositely to one another is provided with an electrode arrangement, characterized in that at least one boundary surface (3, 4) has a waved area with heights (13) and depths (14) as extreme values running parallel to the transverse direction of the body, which waved area is covered by an electrode (5, 6), which electrode covers the full surface of at least a portion of the extremes (13, 14) and is continuous over the waved area.

2. An actuating member according to claim 1, further characterized in that the electrode (5, 6) covers entirely the surface of the waved area.

3. An actuating member according to claim 1 or 2 further characterized in that the electrode (5, 6) is directly connected to the body (2).

4. An actuating member according to one of claims 1 to 3 further characterized in that the extremes (13, 14) have an amplitude (a) which is not larger than 20%o of the thickness (d) of the body (2) between the boundary surfaces (3, 4).

5. An actuating member according to claim 4, further characterized in that the electrode (5, 6) has a thickness (h) which maximally is 10% of the amplitude (a).

6. An actuating member according to claim 4 or 5 further characterized in that the ratio between the amplitude (a) and the period length (L) lies in the range of 0.08 to 0.25.

7. An actuating member according to one of claims 1 to 6, further characterized in that the waved area has a rectangular profile.

8. An actuating element according to claim 7, further characterized in that the rectangular profile has teeth and teeth gaps which are of equal length in the longitudinal direction (12).

9. A method for making an actuating member with a body of elastomer material which body is provided with electrodes on two sides lying oppositely to one another, characterized in that an elastomer is pressed into a mold (7) with a waved surface profile (8) to form a film (9), which film is then left to harden for so short a time that it remains formable, then a further mold (10) with a waved surface (11) is pressed against the other side of the film (9), and after the forming of the outer surface structure a conducting layer is applied to the outer surface.

10. A method according to claim 9, further characterized that the conducting layer is evaporatively applied.
